(19) United States
(12) Patent Application Publication
(10) Pub. No.: US 2009/0183987 A1
(43) Pub. Date: Jul. 23, 2009

(54) Sputter Target Having a Sputter Material Based on TiO2 and Production Method

(75) Inventors: Martin Weigert, Hanau (DE); Christoph Simons, Biebergemünd (DE); Eckehard Männle, Flörsbachtal (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: W.C. Heraeus GmbH, Hanau (DE)

(21) Appl. No.: 12/302,302

(22) PCT Filed: Jun. 6, 2007
(86) PCT No.: PCT/EP2007/005010

§ 371 Date: Nov. 25, 2008

(30) Foreign Application Priority Data
Jun. 9, 2006 (DE) 10 2006 027 029.0

(51) Int. Cl. C23C 14/34; C23C 4/10

(52) U.S. Cl. 204/298.13; 427/453

(57) ABSTRACT

A sputter target is provided having a sputter material based on TiO₂ and made such that the sputter material contains 15-60 mol. % Nb₂O₅. A method for the production of the sputter target includes the following steps:
mixing of TiO₂ and Nb₂O₅ powder in a liquid slurry;
spray granulating this slurry to form TiO₂:Nb₂O₅ mixed oxide granulate; and
plasma spraying this granulate onto a sputter target base body.

### CROSS-REFERENCE TO RELATED APPLICATIONS

This application is a Section 371 of International Application No. PCT/EP2007/005010, filed Jun. 6, 2007, which was published in the German language on Dec. 13, 2007, under International Publication No. WO 2007/141003 A1 and the disclosure of which is incorporated herein by reference.

### BACKGROUND OF THE INVENTION

The invention relates to a sputter target having a sputter material based on TiO₂ and also a production method for this sputter target.

TiO₂ sputter targets are used for the production of high-refraction layers in glass coating (thermal and climate protection glass), for the production of optical filters, and for anti-reflection applications. Here, they are sputtered usually in connection with other metal and metal-oxide layers usually onto a glass substrate. In this way, the TiO₂ layers can be sputtered by means of a metallic titanium target by a so-called reactive process with the addition of gaseous oxygen. The use of oxidic TiO₂ targets, however, allows a simple, controllable sputtering method (direct current or DC sputtering) while excluding or at least substantially reducing the supply of oxygen as a reactive gas into the sputtering process chamber. In this way, the contamination of adjacent sputtering chambers with oxygen is prevented to the greatest degree. The corresponding TiO₂ target materials, however, have lower sputtering rates than, e.g., other metal-oxide targets, such as ZnO.

Such targets are described, e.g., in European Patent EP 0871 794 B1. Here, a TiO₂ target containing 25 wt. % (corresponding to 9.1 mol. %) Nb₂O₅ is described. Increased sputtering rates were not detected. The electrical resistance of the target equals 0.5 Ohm·cm.

German Patent DE 199 58 424 C2 describes a TiO₂ target containing 0.1-5 wt. % Ti, Nb, Cr, Mo, or Ta (corresponding to 0.09-4.3 at. % Nb). However, the mixtures listed here for the target are of a metallic nature, which appear during sputtering as inhomogeneities on the sputtering surface and thus negatively affect the sputtering behavior.

Japanese patent application publication JP 2001058871 describes a TiO₂ target containing 0.05-10 wt. % Nb₂O₅ (corresponding to 0.01-3.2 mol. %), produced as a sinter body, with increased sputtering rates, while at the same time considerable losses in transmission of the produced layers occur.

### BRIEF SUMMARY OF THE INVENTION

The invention is based on the object of making available a sputter target which allows an increased sputtering rate for the production of high-refraction transparent layers.

Surprisingly, targets made of TiO₂ and Nb₂O₅ exhibit sputtering rates up to twice as high as pure TiO₂ targets (with simultaneous reduced energy consumption and high transmission values of the produced layers). Very homogeneous and smooth layers can be produced, and no dust formation occurs during the sputtering process. High transmission values between 80-90% are achieved. The sputter material of the sputter target contains 15-60 mol. % Nb₂O₅ or 1-60 mol. % Nb₂O₅ (preferably 15-40 mol. % Nb₂O₅) and 0.02-1 mol. % In₂O₃. Preferably, the sputter material has a specific resistance of <0.4 Ohm·cm.

The method according to the invention has the following steps:

mixing of TiO₂ and Nb₂O₅ powder in a liquid slurry;

spray granulation of this slurry to form TiO₂:Nb₂O₅ mixed oxide granulate; and

plasma spraying or sintering of this granulate onto a sputter target base body.

The spray granulation guarantees better thorough mixing of the powder with the effect that there is a homogeneous mixture between the TiO₂ and Nb₂O₅ after the plasma spraying or sintering.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a graph showing the dependency of the sputtering rate on the composition mixture according to embodiments of the invention.

### DETAILED DESCRIPTION OF THE INVENTION

### Example 1

TiO₂ is granulated together with 30 mol. % Nb₂O₅ powder. Sinter agglomeration or spray granulation has proven effective as the granulation method. The obtained granulate is screened out <200 μm and processed by atmospheric plasma spraying onto a sputter target body. A sputter target having a diameter of 150 mm and a layer thickness of the sputter material of 2 mm is produced. The specific electrical resistance of the sputter target lies at a maximum of 0.4 Ohm·cm. The sputter target is tested in a DC sputtering system together with a pure TiO₂ sputter target, produced in a comparable manner. 100 nm thick layers are produced. The sputtering results are found in Tables 1a/1b.

TABLE 1a
TiO₂ comparison

| | | | Sputtering rate |
|---|---|---|---|
| % O | % Ar | E [kWh] | [nm/min] |
| 0 | 100 | 88 | 3.0 |
| 10 | 90 | 88 | 3.1 |
| 20 | 80 | 88 | 3.1 |
| 30 | 70 | 92 | 3.1 |

TABLE 1b
TiO₂: Nb₂O₅ 30 mol. %

| | | | Sputtering rate |
|---|---|---|---|
| % O | % Ar | E [kWh] | [nm/min] |
| 0 | 100 | 27 | 11.6 |
| 10 | 90 | 38 | 8.1 |
| 20 | 80 | 51 | 5.8 |
| 30 | 70 | 55 | 5.5 |

The achieved layers are extremely smooth with roughness values RMS <1 nm and homogeneous. The structure of the layers is predominantly amorphous. They exhibit transmission values of 80-90% at 500 nm. Layers that were sputtered with 80-100% Ar achieve transmission values between 85-90%. For comparison, non-coated glass exhibits a transmission of 92%.

### Example 2

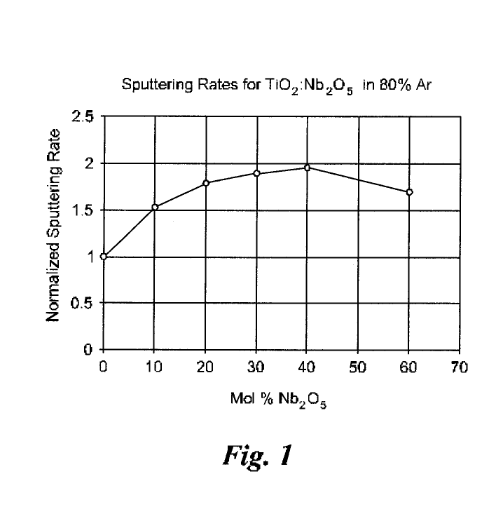

Analogous to Example 1, targets with different concentrations of TiO₂:Nb₂O₅ are produced and DC sputtered. FIG. 1 shows the results as a normalized sputtering rate as a function of the mixture composition. In particular, a high sputtering rate is achieved between approximately 15 and 50 mol. % Nb₂O₅.

### Example 3

A granulate made from TiO₂:Nb₂O₅ 20 mol. % doped with 0.05 mol. % In₂O₃ is produced, and then hot-pressed into a disk. Here, density values of about 4.4 g/cm³ are achieved. The specific electrical resistance equals <0.1 Ohm·cm.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-5. (canceled)

6. A sputter target comprising a sputter material based on TiO₂, wherein the sputter material contains 15-60 mol. % Nb₂O₅.

7. The sputter target according to claim 6, wherein the sputter material has a specific electrical resistance of <0.4 Ohm·cm.

8. A sputter target comprising a sputter material based on TiO₂, wherein the sputter material contains 1-60 mol. % Nb₂O₅ and 0.02-1 mol. % In₂O₃.

9. The sputter target according to claim 8, wherein the sputter material has a specific electrical resistance of <0.4 Ohm·cm.

10. Sputter target according to claim 8, wherein the sputter material contains 15-40 mol. % Nb₂O₅.

11. Sputter target according to claim 9, wherein the sputter material contains 15-40 mol. % Nb₂O₅.

12. A method for production of a sputter target according to claims 6, comprising the following steps:
mixing TiO₂ and Nb₂O₅ powder in a liquid slurry;
spray granulating the slurry to form TiO₂:Nb₂O₅ mixed oxide granulate; and
plasma spraying the granulate onto a sputter target base body.

13. A method for production of a sputter target according to claims 8, comprising the following steps:
mixing TiO₂ and Nb₂O₅ powder in a liquid slurry;
spray granulating the slurry to form TiO₂:Nb₂O₅ mixed oxide granulate; and
plasma spraying the granulate onto a sputter target base body.
